(19) United States
(12) Patent Application Publication
(10) Pub. No.: US 2022/0199405 A1
(43) Pub. Date: Jun. 23, 2022

(54) Method for Producing a Semiconductor Body, A Semiconductor Body and an Optoelectronic Device

(71) Applicant: OSRAM Opto Semiconductors GmbH, Regensburg (DE)

(72) Inventor: Darshan Kundaliya, Middleton, MA (US)

(21) Appl. No.: 17/127,264

(22) Filed: Dec. 18, 2020

(51) Int. Cl. H01L 21/02; H01L 33/26; H01L 31/032

(52) U.S. Cl. CPC H01L 21/02568; H01L 21/0242; H01L 31/032; H01L 33/26; H01L 21/02631

(57) ABSTRACT

In an embodiment, a method includes providing a substrate and epitaxially growing a semiconductor layer of a semiconductor material on the substrate using physical vapor deposition, wherein the semiconductor material has a tetragonal phase, wherein the semiconductor material has the general formula: (In₁₋ₓMₓ)(Te_{1-y}Z_{y}), and wherein M=Ga, Zn, Cd, Hg, Tl, Sn, Pb, Ge, or combinations thereof, Z═As, S, Se, Sb, or combinations thereof, x=0-0.1, and y=0-0.1, or wherein the semiconductor material has the general formula: (In₁₋ₓTlₓ)(Te_{1-y}Se_{y}) with x=0-1 and y=0-1.

### TECHNICAL FIELD

The invention relates to a method for producing a semiconductor body. It further relates to a semiconductor body and an optoelectronic device with such a semiconductor body.

### SUMMARY

Embodiments provide a method for producing a semiconductor body with improved crystalline quality. Further embodiments provide a semiconductor body with improved crystalline quality and an optoelectronic device comprising a semiconductor body with improved crystalline quality.

According to at least one embodiment, a method for producing a semiconductor body is provided. A semiconductor body comprises at least one semiconductor layer. In particular, the semiconductor body can be configured to emit or receive electromagnetic radiation. For example, the at least one semiconductor layer of the semiconductor body can be configured to emit or receive radiation such as infrared and/or visible radiation.

According to at least one embodiment, the method comprises providing a substrate. The substrate is the base material on which components, parts, and/or layers of the semiconductor body are grown, applied, deposited, arranged, and/or provided. The substrate is a crystalline substrate with a defined orientation of the crystal lattice of the substrate material. In other words, the substrate has a specific crystal structure. In particular, the substrate has a high thermal conductivity, for example, of approximately 30 W/mK. For example, the substrate is a sapphire substrate that comprises or consist of sapphire.

According to at least one embodiment, the method comprises epitaxially growing a semiconductor layer of a semiconductor material on the substrate using physical vapor deposition.

Physical vapor deposition is characterized by a process in which the semiconductor material is provided in a solid or liquid phase, evaporated to the gas phase, transported to the substrate, and deposited onto the substrate as a solid phase. Epitaxial growth refers to a material deposition or growth in which a crystalline layer is formed with one or more well-defined orientations with respect to the crystalline substrate. In other words, the semiconductor layer grows epitaxially because of the close lattice match between the substrate and the semiconductor material.

The epitaxially grown semiconductor layer is an epitaxial thin film with single crystalline quality. In other words, the as-deposited thin films of the semiconductor material exhibit epitaxial quality.

According to at least one embodiment, the semiconductor material has the general formula (In₁₋ₓMₓ)(Te_{y1-y}Z_{y}), wherein M=Ga, Zn, Cd, Hg, Tl, Sn, Pb, Ge, or combinations thereof, Z═As, S, Se, Sb, or combinations thereof, x=0-0.1, and y=0-0.1. Alternatively, the semiconductor material has the general formula (In₁₋ₓTlₓ)(Te_{1-y}Se_{y}), wherein x=0-1 and y=0-1.

With x=0 and y=0, the semiconductor material is stoichiometric InTe. Both In and Te can independently from one another be replaced with at least one dopant element to an extent of at most 10 atomic percent (at %) without changing the crystal system or phase of the semiconductor material.

There is an exception to above statements for the case of Tl and Se as dopant elements. These dopant elements can replace In and Te completely to form a TlSe material without affecting the crystal structure.

For producing an epitaxial semiconductor layer, a target is used on which the semiconductor material is provided. The semiconductor material is evaporated from the target and subsequently epitaxially grown on the substrate. For producing a semiconductor layer of stoichiometric InTe, an InTe target, in particular an InTe target with a purity of, for example, 99.99% can be used. For producing a semiconductor layer of doped InTe, a doped target can be used. A doped target is, for example, an InTe target that is already doped in the goal doping concentration with the at least one dopant element so that the deposition on the substrate can be both epitaxially and doped.

The ionic radius of the dopant element and/or the electronic properties of the dopant element selectively changes the electronic properties of the stoichiometric InTe. The insertion of dopant elements into the stoichiometric InTe can be used to tune the band gap of the semiconductor material without affecting the phase of pure InTe.

In particular, the semiconductor material has a narrow bandgap between and including 0.1 eV and 1.0 eV. For example, stoichiometric InTe has a bandgap between and including 0.3 eV and 0.6 eV.

In particular, the ionic radii of dopant elements relative to indium or tellurium determines the changes in the bandgap of the doped material. Dopant elements with a larger ionic radius increases the lattice constant of the stoichiometric InTe and hence, reduce the bandgap. For example, epitaxially grown stoichiometric InTe has a bandgap between and including 0.3 and 0.6 eV. Doping the Tellurium (Te) with Selenium (Se) in In(Te_{1-y}Se_{y}) will decrease the lattice constant and thus increase the bandgap. Replacing both In and Te with Tl and Se, respectively, will decrease the lattice constant and increase the bandgap of TlSe to 0.6-0.8 eV from 0.3-0.6 eV of stoichiometric InTe.

In particular, the semiconductor material is configured to emit or detect radiation in the infrared wavelength range.

According to at least one embodiment, the semiconductor material has a tetragonal phase. The tetragonal phase or, in crystallography, the tetragonal crystal system is one of the seven crystal systems. Tetragonal crystal lattices result from stretching a cubic lattice so that the cube becomes a rectangular prism with a square base and a height. In particular, the semiconductor material forms into tetragonal symmetry with a space group I4/mcm (TlSe-type).

For example, the structure of the stoichiometric InTe can be further described by the formula In⁺In³⁺Te₂²⁻. In³⁺ ions are tetrahedrally coordinated with four Te²⁻ ions whereas In⁺ ions are surrounded by eight Te²⁻ ions in a tetragonal antiprismatic arrangement. This indicates that In³⁺ ions and In⁺ ions occupy two distinct crystallographic positions and prevents free transfer of electrons from the In⁺ ions to the In³⁺ ions. In particular, the tetragonal phase of the semiconductor material remains intact even if at most 10 at % of at least one dopant element is introduced into the material.

According to at least one embodiment, the method for producing a semiconductor body comprises the steps providing a substrate, epitaxially growing a semiconductor layer of a semiconductor material on the substrate using physical vapor deposition, wherein the semiconductor material has a tetragonal phase, and wherein the semiconductor material has the general formula (In₁₋ₓMₓ)(Te_{1-y}Z_{y}), wherein M=Ga, Zn, Cd, Hg, Tl, Sn, Pb, Ge, or combinations thereof, Z═As, S, Se, Sb, or combinations thereof, x=0-0.1, and y=0-0.1, or wherein the semiconductor material has the general formula (In₁₋ₓTlₓ)(Te_{1-y}Se_{y}), wherein x=0-1 and y=0-1.

With such a method, an epitaxially grown semiconductor layer of a stoichiometric InTe material or a doped InTe material can be produced on a substrate. Thus, semiconductor layers of a narrow bandgap material can be produced in a thin film form with a single crystalline quality and the bandgap of the semiconductor layer can be tuned by doping. Epitaxially growing semiconductor layers on substrates is enabling high throughput of photonic components at low thermal budget in a manufacturing environment, while controlling the size and spatial distribution of the semiconductor layer and enabling device fabrication in large volume on large area wafers as well as multi-layer quantum well structures for efficient device fabrication on large scale. Further, epitaxial films enable the subsequent control of conformal coating of additional materials such as antireflective coatings.

According to at least one embodiment, the semiconductor layer is a stoichiometric InTe layer. Stoichiometric InTe has a molecular weight of 242.42 g/mol and forms into tetragonal symmetry with a space group I4/mcm (TlSe-type). The structure of the stoichiometric InTe is already described above in more detail. The melting point of the InTe material is approximately 667° C. and the density is approximately 6.30 g/cm³. Epitaxially grown stoichiometric InTe has a narrow bandgap of between and including 0.3 eV and 0.6 eV. Stoichiometric InTe can be deposited in a thin film form with a single crystalline quality.

According to at least one embodiment, the substrate is transparent for infrared and/or visible radiation. In other words, the substrate transmits incident electromagnetic radiation with a wavelength in the infrared and/or visible wavelength range. In particular, the substrate transmits at least visible radiation (380 nm-800 nm) and near infrared radiation (800 nm-1.4 μm). Preferably, the substrate additionally transmits mid infrared radiation (1.4 μm-3 μm) and far infrared radiation (3 μm-6 μm). In particular, the substrate transmits at least 80%, in particular at least 90%, preferably at least 95%, particularly preferably at least 99% of the incident infrared and/or visible radiation. A transparent substrate advantageously does not obstruct radiation pathways for a wide range of electromagnetic radiation in the infrared and/or visible wavelength spectrum in the semiconductor body.

According to at least one embodiment, the substrate is a r-Al₂O₃ substrate or a YSZ (111) substrate. In other words, the substrate is a r-cut sapphire or yttria-stabilized zirconia (YSZ) with (111) plane orientation. Yttria-stabilized zirconia (YSZ) is a ceramic in which the metastable tetragonal crystal structure of zirconium dioxide is made stable at room temperature by an addition of yttrium oxide. A r-Al₂O₃ substrate as well as a YSZ (111) substrate comprises a lattice structure that matches the lattice structure of the semiconductor material. A r-Al₂O₃ substrate or a YSZ (111) substrate is thus advantageous for epitaxially growing the semiconductor material. Furthermore, a r-Al₂O₃ substrate or a YSZ (111) substrate is transparent for infrared and visible radiation and has a high thermal conductivity which is advantageous for the use in optoelectronics.

According to at least one embodiment, the substrate is an epitaxial CeO₂/r-Al₂O₃ substrate or a CeO₂/YSZ (111) substrate. In particular, a r-sapphire substrate and/or a YSZ (111) substrate is used for growing an epitaxial CeO₂ sacrificial layer. The layer stacks CeO₂/r-Al₂O₃ and/or CeO₂/YSZ (111) can be used as substrates for growing the epitaxial semiconductor layer of the semiconductor material. Alternatively, the YSZ (111) substrate and/or or the sapphire substrate can be detached at the interface of the CeO₂ sacrificial layer by laser lift-off.

According to at least one embodiment, the semiconductor layer has a thickness between and including 5 nm and 5000 nm, in particular between and including 5 nm and 500 nm. A semiconductor layer with a thickness between and including 5 nm and 5000 nm is particularly advantageous for producing a thin film with a single crystalline quality.

According to at least one embodiment, the physical vapor deposition is performed by means of pulsed laser deposition (PLD), vapor-phase epitaxy (VPE), metal organic vapor-phase epitaxy (MOVPE), molecular-beam epitaxy (MBE), magnetron sputtering, electron-beam epitaxy, thermal evaporation epitaxy, or pulsed electron epitaxy. In particular, the semiconductor layer is epitaxially grown by pulsed laser deposition. These physical vapor deposition methods are particularly advantageous for producing a semiconductor layer in a thin film form with a single crystalline quality.

According to at least one embodiment, the physical vapor deposition is performed at a temperature between and including room temperature (e.g. 20° C.) and 900° C., in particular between and including 300° C. and 900° C., preferably between and including 500° C. and 700° C., for example 600° C. or 650° C. In particular, the deposition temperature is the substrate temperature. Deposition temperatures and/or substrate temperatures between and including room temperature and 900° C. are particularly advantageous for producing a semiconductor layer in a thin film form with a single crystalline quality.

According to at least one embodiment, the physical vapor deposition is performed at a pressure between and including 1×10⁻⁶ Torr and 750 Torr, in particular between and including 1×10⁻⁶ Torr and 1 Torr, preferably between and including 1×10⁻⁶ Torr and 400 mTorr, for example 10 mTorr. In other words, the pressure in the deposition chamber during physical vapor deposition is selected between and including vacuum and 1 Torr. A pressure between and including 1×10⁻⁶ Torr and 750 Torr is particularly advantageous for producing a semiconductor layer in a thin film form with a single crystalline quality.

According to at least one embodiment, the physical vapor deposition is performed in a gas environment. Gas environment is to be understood as the gas that is present in the deposition chamber during depositing or growing the semiconductor layer. In particular, the gas present in the deposition chamber is substantially responsible for the pressure in the deposition chamber. For example, the semiconductor layer can be grown in an argon environment or an oxygen environment.

According to at least one embodiment, the physical vapor deposition is performed with a deposition time between and including 10 minutes and 30 minutes, for example 20 minutes. A deposition time between and including 10 minutes and 30 minutes is particularly advantageous for producing a semiconductor layer in a thin film form with a single crystalline quality.

According to at least one embodiment, the pulsed laser deposition is performed with a laser energy density between and including 0.5 J/cm² and 5 J/cm², for example, 2 J/cm², and a laser repetition rate between and including 1 Hz and 10 Hz, for example, 5 Hz. This is particularly advantageous for producing a semiconductor layer in a thin film form with a single crystalline quality.

According to at least one embodiment, a surface of the semiconductor layer is structurally engineered after epitaxially growing the semiconductor layer. The surface of the semiconductor layer is modified, for example, by changing the surface structure, the surface roughness, the surface topology, the surface texture, the surface morphology, and/or the surface composition. In particular, the surface of the semiconductor layer is structurally engineered in a targeted and controlled manner. For example, the surface of the semiconductor layer can be roughened or structured for increased light outcoupling.

According to at least one embodiment, during the structurally engineering, micron- and/or nano-sized structures are formed on the surface of the semiconductor layer by means of etching, in particular by chemical etching or laser etching. In particular, the etching is part of a photolithography process. The structures formed on the surface of the semiconductor layer can be emphasized with respect to the surface of the semiconductor layer in direct vicinity to the structures and can protrude over areas of the surface of the semiconductor layer which is arranged adjacent to the structures. In particular, each structure forms an elevation. Micron- and/or nano-sized is to be understood that each structure has a diameter and/or a height of between and including 1 nm and 50 μm. The structures can have a form of a pyramid, a truncated pyramid, an inverted pyramid, a cone, a truncated cone, an inverted cone and/or a cylinder, for example.

In particular, the structure on the semiconductor layer is an optical nanostructure. For example, high aspect ratio surface structures such as photonic crystals are fabricated on the semiconductor layer to affect the motion of photons entering or leaving the semiconductor layer.

According to at least one embodiment, the micron- and/or nano-sized structures are formed ordered or randomized. For example, the structures are formed ordered as a periodic optical nanostructure such as a photonic crystal. It is also possible that the structures are formed as an aperiodic pattern. Thus, the structures can be tailored to a specific effect.

According to at least one embodiment, a further semiconductor layer of a further semiconductor material is epitaxially grown on the semiconductor layer. In particular, the further semiconductor layer is directly grown on the semiconductor layer.

According to at least one embodiment, a surface of the further semiconductor layer is structurally engineered. Such a structurally engineering is already disclosed for the semiconductor layer and also applies to the further semiconductor layer.

According to at least one embodiment, the further semiconductor material has a tetragonal phase, and the general formula (In₁₋ₓMₓ)(Te_{1-y}Z_{y}), wherein M=Ga, Zn, Cd, Hg, Tl, Sn, Pb, Ge, or combinations thereof, Z═As, S, Se, Sb, or combinations thereof, x=0-0.1, and y=0-0.1, or the general formula (In₁₋ₓTlₓ)(Te_{1-y}Se_{y}), wherein x=0-1 and y=0-1.

According to at least one embodiment, the semiconductor material and the material of the further semiconductor layer are doped differently. One layer can be p-type doped for creating holes as charge carriers by selecting a dopant with lower valence state. In other words, the layer is p-type conductive or has a p-type conductivity. The other layer can be n-type doped for creating electrons as charge carriers by selecting a dopant with a higher valence state. In other words, the layer is n-type conductive or has a n-type conductivity. In particular, the n-type doping and the p-type doping is achieved by ion implantation or lattice site substitution. For example, In³⁺ ions can be replaced by Si⁴⁺ or Sn⁴⁺ ions in order to form a n-type doped semiconductor layer.

For example, the semiconductor material of the semiconductor layer can be p-type doped and the further semiconductor material of the further semiconductor layer can be n-type doped. Alternatively, the semiconductor material can be n-type doped and the further semiconductor material can be p-type doped. Thus, it is possible to create a junction in a semiconductor body while using only one semiconductor material with different n-type and p-type dopants.

According to at least one embodiment, at least one additional material is deposited on the semiconductor layer. The additional material can be deposited as a layer or a coating. Alternatively or additionally, the additional material can be deposited on a further semiconductor layer—if present. In particular, the additional material is deposited directly on the semiconductor layer. Depositing an additional material on an epitaxial film such as the semiconductor layer can be carried out conformal to the surface of the semiconductor layer so that a conformal coating of the surface is achieved. For example, the additional material is an antireflective material for an antireflective coating.

Further embodiments relate to a semiconductor body. The semiconductor body described here is preferably produced with the method described here. Features and embodiments of the semiconductor body are therefore also disclosed for the method and vice versa.

According to at least one embodiment, the semiconductor body comprises a semiconductor layer of a semiconductor material, wherein the semiconductor layer is epitaxially grown, wherein the semiconductor layer has a bandgap between and including 0.1 eV and 1.0 eV, wherein the semiconductor material has a tetragonal phase, and wherein the semiconductor material has the general formula (In₁₋ₓMₓ)(Te_{1-y}Z_{y}), wherein M=Ga, Zn, Cd, Hg, Tl, Sn, Pb, Ge, or combinations thereof, Z═As, S, Se, Sb, or combinations thereof, x=0-0.1, and y=0-0.1, or wherein the semiconductor material has the general formula (In₁₋ₓTlₓ)(Te_{1-y}Se_{y}), wherein x=0-1 and y=0-1.

The semiconductor material is stoichiometric InTe with a tetragonal phase and a bandgap between and including 0.1 eV and 1.0 eV or a doped InTe with a tetragonal phase and the general formula (In₁₋ₓMₓ)(Te_{1-y}Z_{y}). In the doped InTe, at most 10 at % of the indium atoms and/or the tellurium atoms are independently of one another replaced with at least one dopant element. The indium atoms can be replaced, for example, with Ga, Zn, Cd, Hg, Tl, Sn, Pb, Ge, or combinations thereof, and the tellurium atoms can be replaced, for example, with As, S, Se, Sb, or combinations thereof. Introducing dopant elements increases or lowers the bandgap of the semiconductor material depending on the respective dopant element. Introducing dopant elements with a concentration of at most 10 at % does not affect the tetragonal phase of the material so that the bandgap of the semiconductor material can be tuned by introducing dopant elements without the semiconductor layer losing its epitaxial quality.

There is an exception to above statements for the case of Tl and Se as dopant elements. These dopant elements can replace In and Te completely to form a TlSe material without affecting the crystal structure.

An epitaxially grown semiconductor layer is a crystalline layer with one or more well-defined orientations with respect to the crystalline substrate on which the semiconductor layer is grown. In other words, the semiconductor layer grows epitaxially because of the close lattice match between the substrate and the semiconductor material.

Such a semiconductor body comprises an epitaxially grown semiconductor layer of a stoichiometric InTe material or a doped InTe material. The semiconductor layer is an epitaxial thin-film with a single crystalline quality of a material with a narrow bandgap that can be tuned by doping. Such a semiconductor body can advantageously be used in optoelectronics.

According to at least one embodiment, the semiconductor body comprises a substrate. The substrate is, in particular, transparent for radiation in the infrared and/or visible wavelength range and has a high thermal conductivity. For example, the substrate is r-cut sapphire (r-Al₂O₃), YSZ (111), CeO₂/r-Al₂O₃, or CeO₂/YSZ (111). In particular, the substrate comprises a lattice structure that matches the lattice structure of the tetragonal phased semiconductor material.

According to at least one embodiment, the semiconductor body is free of a substrate. In particular, the substrate used for growing the semiconductor layer is detached from the semiconductor layer by laser lift-off. For example, the semiconductor layer is grown on CeO₂/r-Al₂O₃ or CeO₂/YSZ (111) and, subsequently, the YSZ (111) substrate and/or the sapphire substrate are detached at the interface of the CeO₂ sacrificial layer by laser lift-off.

According to at least one embodiment, the semiconductor layer is a stoichiometric InTe layer. Stoichiometric InTe has a molecular weight of 242.42 g/mol and forms into tetragonal symmetry with a space group I4/mcm (TlSe-type). The structure of the stoichiometric InTe is described above in conjunction with the method in more detail. The melting point of the InTe material is approximately 667° C. and the density is approximately 6.30 g/cm³. Epitaxially grown stoichiometric InTe has a narrow bandgap of between and including 0.3 eV and 0.6 eV and a single crystalline quality.

According to at least one embodiment, a surface of the semiconductor layer comprises micron- and/or nano-sized structures. The structures can have a diameter and/or a height of between and including 1 nm and 50 μm. The structures have a form of a pyramid, a truncated pyramid, an inverted pyramid, a cone, a truncated cone, an inverted cone, a cylinder, for example. For example, the surface of the semiconductor layer comprises high aspect ratio surface structures such as photonic crystals to affect the motion of photons entering or leaving the semiconductor layer.

According to at least one embodiment, the micron- and/or nano-sized structures are arranged ordered or randomized. For example, the structures are arranged in an ordered manner, for example, as a periodic optical nanostructure such as a photonic crystal. It is also possible that the structures are arranged as an aperiodic pattern. Thus, the structures can be tailored to a specific effect, for example, improving the outcoupling of radiation.

According to at least one embodiment, a further semiconductor layer of a further semiconductor material is arranged on the semiconductor layer. In particular, the further semiconductor layer is epitaxially grown. In particular, the further semiconductor material has a tetragonal phase, and has the general formula (In₁₋ₓMₓ)(Te_{1-y}Z_{y}), wherein M=Ga, Zn, Cd, Hg, Tl, Sn, Pb, Ge, or combinations thereof, Z═As, S, Se, Sb, or combinations thereof, x=0-0.1, and y=0-0.1, or the general formula (In₁₋ₓTlₓ)(Te_{1-y}Se_{y}), wherein x=0-1 and y=0-1. In particular, the further semiconductor layer is arranged directly on the semiconductor layer.

According to at least one embodiment, the semiconductor material and the material of the further semiconductor layer are doped differently. For example, the semiconductor material of the semiconductor layer can be p-type doped and the further semiconductor material of the further semiconductor layer can be n-type doped. Alternatively, the semiconductor material can be n-type doped and the further semiconductor material can be p-type doped. Thus, it is possible to create a junction in a semiconductor body while using only one semiconductor material with different n-type and p-type dopants. Thus, it is possible to create a junction in a semiconductor body while using only one semiconductor material with different dopants.

Further embodiments relates to an optoelectronic device. Preferably, the optoelectronic device described here comprises a semiconductor body described above produced with the method described above. Features and embodiments of the optoelectronic component are therefore also disclosed for the semiconductor body and the method and vice versa.

According to at least one embodiment, the optoelectronic device comprises a semiconductor body described above, wherein the optoelectronic device forms at least one of the elements: detector, sensor, emitter, switching device, photo responsive device.

The features of the semiconductor body have already been disclosed in conjunction with the method for producing a semiconductor body and the semiconductor body and also apply to the semiconductor body in the optoelectronic device.

A detector or sensor is a device for measuring electromagnetic radiation incident on the detector or sensor. An emitter is a device that is configured to emit electromagnetic radiation, in particular of a specific wavelength range. A switching device is a device that opens and closes electrical circuits. A photo responsive device is a photoreceptor.

For elements detecting or receiving electromagnetic radiation, the semiconductor layer of the semiconductor body is configured to detect or receive the electromagnetic radiation. For elements emitting electromagnetic radiation, the semiconductor layer of the semiconductor body is configured to emit electromagnetic radiation, in particular electromagnetic radiation in the visible wavelength range.

Such an optoelectronic device advantageously exploits the properties of the epitaxially grown semiconductor material in the semiconductor layer in the semiconductor body. According to at least one embodiment, the semiconductor body comprises a semiconductor layer and a further semiconductor layer, wherein the semiconductor layer and the further semiconductor layer are doped differently. For example, the semiconductor material of the semiconductor layer can be p-type doped and the further semiconductor material of the further semiconductor layer can be n-type doped. Alternatively, the semiconductor material can be n-type doped and the further semiconductor material can be p-type doped. Thus, it is possible to create a junction in a semiconductor body while using only one semiconductor material with different n-type and p-type dopants.

According to at least one embodiment, an infrared or visible emitting material or an infrared or visible detecting material is arranged on the semiconductor body or on the surface of the substrate facing away from the semiconductor layer. The material can be deposited or bonded or epitaxially grown on the semiconductor layer or the further semiconductor layer of the semiconductor body or on the surface of the substrate facing away from the semiconductor body. The material can be arranged in form of a layer or a coating.

In particular, the material detects or emits radiation with a different wavelength range than the semiconductor material of the semiconductor layer. Thus, the optoelectronic component is configured for multi-wavelength emission or detection by staking or bonding two components of different wavelengths on to a substrate having transmittance in a broad range of the electromagnetic spectrum.

For example, the optoelectronic component comprises a sapphire substrate and a semiconductor body with at least one semiconductor layer of stoichiometric InTe, wherein the optoelectronic component is an infrared emitter. On the surface of the substrate facing away from the semiconductor layer, a detector or emitter of a different wavelength is arranged for additional detection or emission.

For example, a GaN blue LED is arranged on the surface of the substrate facing away from the semiconductor body for emitting radiation in the visible wavelength range. This enables a hybrid emitter emitting visible and infrared radiation using a single substrate.

According to at least one embodiment, a surface of the infrared or visible emitting or detecting material comprises a surface structure. The surface structure is provided for adding topographical functionality. In particular, the surface of the infrared or visible emitting or detecting material is roughened or structured. For example, the surface structure of the infrared or visible emitting or detecting material can improve the outcoupling or incoupling of radiation.

According to at least one embodiment, a lens is arranged on the semiconductor body. The lens can be in direct contact to the semiconductor body or the lens and the semiconductor body can be spaced apart. In particular, the lens is arranged in such a way that radiation leaving the semiconductor body or being directed on the semiconductor body at least partially or completely passes through the lens. The lens can have different shapes, for example hemispherical, convex or concave. For example, the lens is a collecting lens. A lens can be used advantageously for additional and efficient outcoupling or incoupling of electromagnetic radiation.

### BRIEF DESCRIPTION OF THE DRAWINGS

Advantageous embodiments and developments of the method for producing a semiconductor body, a semiconductor body, and an optoelectronic device will become apparent from the exemplary embodiments described below in conjunction with the figures.

In the figures:

FIGS. 1-5 each show a schematic illustration of a semiconductor body according to different embodiments;

FIGS. 6 and 7 each show a schematic illustration of an optoelectronic device according to different embodiments; and

FIG. 8 shows an x-ray diffractogram of a semiconductor body according to an embodiment and an x-ray diffractogram of r-cut sapphire.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

### DETAILED DESCRIPTION OF ILLUSTRATIVE EMBODIMENTS

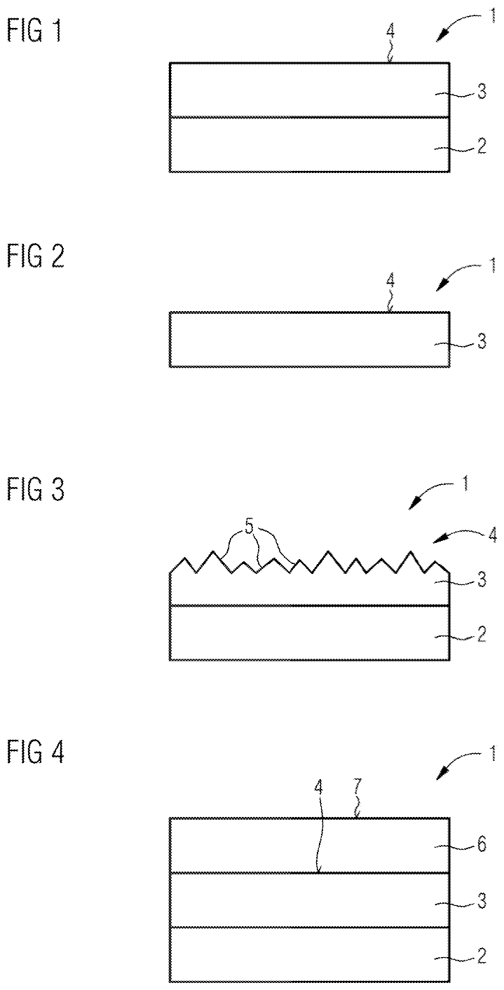

FIGS. 1-5 each show a schematic illustration of a semiconductor body 1.

Each semiconductor body 1 in FIGS. 1-5 comprises an epitaxially grown semiconductor layer 3. The semiconductor material of the semiconductor layer 3 is stoichiometric InTe with a tetragonal phase and a bandgap between and including 0.3 eV and 0.6 eV or a doped InTe with a tetragonal phase and the general formula (In₁₋ₓMₓ)(Te_{y}N_{1-y}). In the doped InTe, at most 10 at % of the indium atoms and/or the tellurium atoms are independently of one another replaced with at least one dopant element. The indium atoms can be replaced, for example, with Ga, Zn, Cd, Hg, Tl, Sn, Pb, Ge, or combinations thereof, and the tellurium atoms can be replaced, for example, with As, S, Se, Sb, or combinations thereof. Introducing dopant elements with a concentration of at most 10 at % does not affect the tetragonal phase of the material so that the bandgap of the semiconductor material can be tuned by introducing dopant elements without the semiconductor layer losing its epitaxial quality.

There is an exception to above statements for the case of Tl and Se as dopant elements. These dopant elements can replace In and Te completely to form a TlSe material without affecting the crystal structure.

The semiconductor body 1 in FIG. 1 further comprises a substrate 2. The substrate 2 is a crystalline substrate with a defined crystal structure. In particular, the substrate is transparent in the infrared and/or visible wavelength range and has a high thermal conductivity. For example, the substrate is r-cut sapphire (r-Al₂O₃) or YSZ (111).

Alternatively, as shown in FIG. 2, the semiconductor body 1 is free of a substrate. The substrate 2, on which the semiconductor layer 3 is grown, is, for example, detached at the interface of a sacrificial layer such as CeO₂ by laser liftoff.

A semiconductor body comprising an epitaxially grown semiconductor layer of stoichiometric InTe was produced as follows:

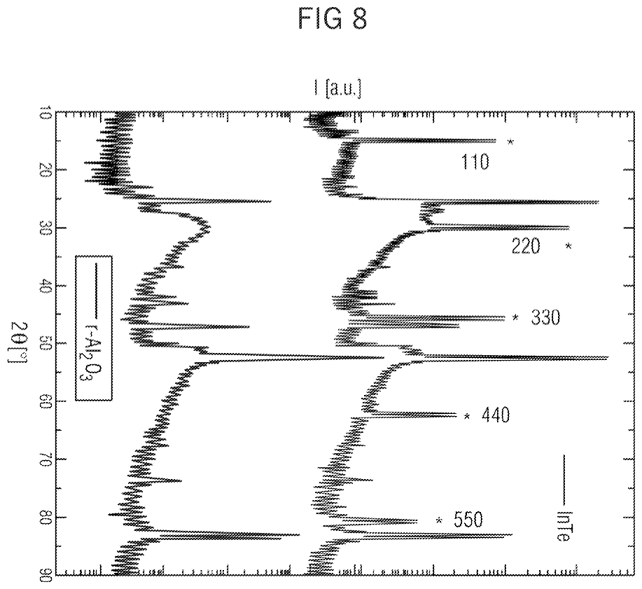

A thin film of stoichiometric InTe was grown on a r-sapphire (r-Al₂O₃) substrate using pulsed laser deposition (PLD). An InTe target with a purity of 99.99% was used for vaporizing the InTe. The deposition of the vaporized InTe onto the substrate was carried out in an argon environment with a deposition pressure of 10 mTorr, a substrate temperature of 650° C., a deposition time of 20 min, a laser energy density of approximately 2 J/cm², and a laser repetition rate of 5 Hz. The InTe film grew epitaxially due to the close lattice matching between the substrate and InTe. The InTe film exhibited epitaxial quality (FIG. 8).

The semiconductor body 1 in FIG. 3 comprises a substrate 2, an epitaxially grown semiconductor layer 3, and structures 5 on a surface 4 of the semiconductor layer 3. Alternatively, the semiconductor body 1 can be free of the substrate 2 (not shown).

The structures 5 are produced by etching, for example chemical etching or laser etching. The structures 5 are micron- and/or nano-sized structures that are arranged ordered or randomized. The structures 5 can have a form of a pyramid, a truncated pyramid, an inverted pyramid, a cone, a truncated cone, an inverted cone, and/or a cylinder. The structures 5 can have a diameter and/or a height between and including 1 nm and 50 μm. The structures 5 can form a periodic or an aperiodic pattern. For example, the structures 5 form a periodic optical nanostructure such as a photonic crystal.

The semiconductor body 1 in FIG. 4 comprises a substrate 2, an epitaxially grown semiconductor layer 3, and a further epitaxially grown semiconductor layer 6 on the surface 4 of the semiconductor layer 3. Alternatively, the semiconductor body 1 can be free of the substrate 2 (not shown).

The further semiconductor material of the further semiconductor layer 6 is, in particular, a semiconductor material as disclosed as the semiconductor material of the semiconductor layer 3.

The semiconductor material of the semiconductor layer 3 and the further semiconductor material of the further semiconductor layer 6 can be doped differently. For example, the semiconductor material can be p-type doped and the further semiconductor material can be n-type doped. Alternatively, the semiconductor material can be n-type doped and the further semiconductor material can be p-type doped.

The surface 7 of the further semiconductor layer 6 can comprise structures 5 (FIG. 5). The structures 5 are already described in conjunction with FIG. 3.

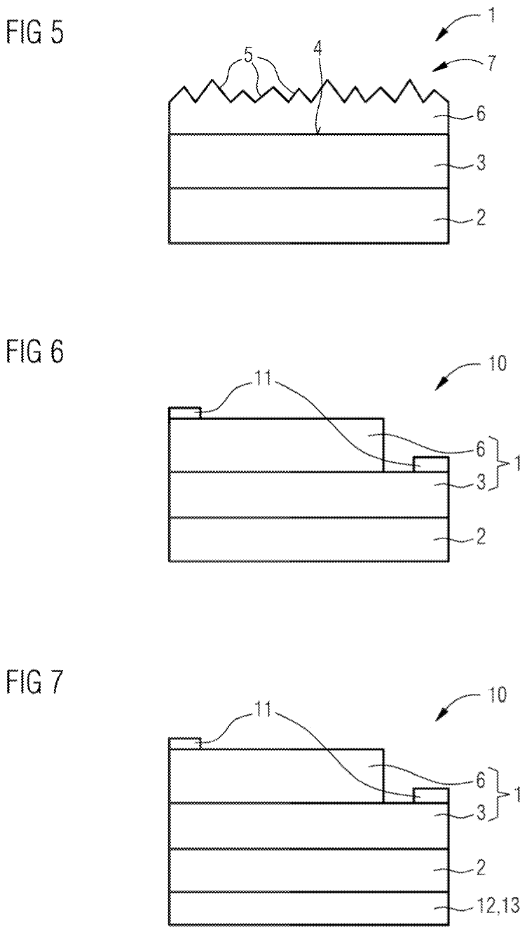

FIG. 6 shows a schematic illustration of an optoelectronic device 10. The optoelectronic device 10 comprises a semiconductor body 1 on a substrate 2 and electrodes 11. The semiconductor body 1 comprises a semiconductor layer 3 and a further semiconductor layer 6. The substrate 2 can be the growth substrate of the semiconductor layers 3, 6 of the semiconductor body 1 or a carrier substrate for the semiconductor body 1. For example, the substrate 2 is a r-Al₂O₃ substrate or a YSZ (111) substrate. In particular, the optoelectronic device 10 is configured for emitting infrared radiation.

The semiconductor material 3 and the material of the further semiconductor layer 6 are doped differently to create a junction in a semiconductor body 1 while using only one semiconductor material, for example, stoichiometric InTe. For example, the material of semiconductor layer can be p-type doped and the material of the further semiconductor layer can be n-type doped. Alternatively, the semiconductor material can be n-type doped and the material of the further semiconductor layer can be p-type doped. The n-type doping and the p-type doping are achieved by ion implantation or lattice site substitution. For example, In³⁺ ions can be replaced by Si⁴⁺ or Sn⁴⁺ ions in order to form a n-type doped semiconductor layer.

FIG. 7 shows the optoelectronic component of FIG. 6, further comprising an infrared or visible emitting material 12 or an infrared or visible detecting material 13 arranged on the surface of the substrate 2 facing away from the semiconductor body 1. The material 12, 13 can be deposited or bonded or epitaxially grown on the surface of the substrate 2 in form of a layer or a coating.

For example, the semiconductor body 1 is configured as an infrared emitter and arranged on the substrate 2. A GaN blue LED is arranged on the opposite side of the substrate 2 as a visible emitting material 12. The optoelectronic component 10 is thus a hybrid emitter emitting visible and infrared radiation using a single substrate 2.

Alternatively, the material 12, 13 can be deposited or bonded or epitaxially grown on the semiconductor body 1 (not shown).

FIG. 8 shows x-ray diffractograms (XRD) in which the intensity I in arbitrary units a.u. is plotted against 2e in °. FIG. 8 shows the XRD of a stoichiometric InTe thin film deposited on a r-Al₂O₃ substrate (r-cut sapphire substrate) (top) and the XRD of a r-Al₂O₃ substrate (r-cut sapphire substrate) for comparison purposes (bottom). The peaks marked with an asterisk (*) in the XRD of the InTe film correspond to multiples of the same d-spacing indicating an epitaxial InTe thin film.

The features and exemplary embodiments described in connection with the figures can be combined with each other according to further exemplary embodiments, even if not all combinations are explicitly described. Furthermore, the exemplary embodiments described in connection with the figures may have alternative or additional features as described in the general part.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A method for producing a semiconductor body, the method comprising:
providing a substrate; and
epitaxially growing a semiconductor layer of a semiconductor material on the substrate using physical vapor deposition,
wherein the semiconductor material has a tetragonal phase,
wherein the semiconductor material has the general formula: (In₁₋ₓMₓ)(Te_{1-y}Z_{y}), and
wherein M=Ga, Zn, Cd, Hg, Tl, Sn, Pb, Ge, or combinations thereof, Z═As, S, Se, Sb, or combinations thereof, x=0-0.1, and y=0-0.1, or
wherein the semiconductor material has the general formula: (In₁₋ₓTlₓ)(Te_{1-y}Se_{y}) with x=0-1 and y=0-1.

2. The method according to claim 1, wherein the semiconductor layer is a stoichiometric InTe layer.

3. The method according to claim 1, wherein the substrate is transparent for infrared and/or visible radiation.

4. The method according to claim 1, wherein the substrate is a r-Al₂O₃ substrate or a yttria-stabilized zirconia (YSZ) substrate.

5. The method according to claim 1, wherein the semiconductor layer has a thickness between 5 nm to 5000 nm inclusive.

6. The method according to claim 1, wherein the physical vapor deposition is performed by a pulsed laser deposition, a vapor-phase epitaxy, a metal organic vapor-phase epitaxy, a molecular-beam epitaxy, a magnetron sputtering, an electron-beam epitaxy, a thermal evaporation epitaxy, or a pulsed electron epitaxy.

7. The method according to claim 1, wherein the physical vapor deposition is performed at a temperature between room temperature and 900° C. inclusive.

8. The method according to claim 1, wherein the physical vapor deposition is performed at a pressure between 1×10⁻⁶ Torr and 750 Torr inclusive.

9. The method according to claim 1, wherein a surface of the semiconductor layer is structurally engineered after epitaxially growing the semiconductor layer.

10. The method according to claim 9, wherein, during the structurally engineering, micron- and/or nano-sized structures are formed on the surface of the semiconductor layer by etching.

11. The method according to claim 1, wherein a further semiconductor layer of a further semiconductor material is epitaxially grown on the semiconductor layer.

12. The method according to claim 11,
wherein the further semiconductor material has a tetragonal phase,
wherein the further semiconductor material has the general formula: (In₁₋ₓMₓ)(Te_{1-y}Z_{y}), and
wherein M=Ga, Zn, Cd, Hg, Tl, Sn, Pb, Ge, or combinations thereof, Z═As, S, Se, Sb, or combinations thereof, x=0-0.1, and y=0-0.1, or
wherein the further semiconductor material has the general formula (In₁₋ₓTlₓ)(Te_{1-y}Se_{y}), wherein x=0-1 and y=0-1.

13. A semiconductor body comprising:
a semiconductor layer of a semiconductor material,
wherein the semiconductor layer is epitaxially grown,
wherein the semiconductor layer has a bandgap between 0.1 eV and 1.0 eV inclusive,
wherein the semiconductor material has a tetragonal phase, and
wherein the semiconductor material has the general formula: (In₁₋ₓMₓ)(Te_{1-y}Z_{y}), and
wherein M=Ga, Zn, Cd, Hg, Tl, Sn, Pb, Ge, or combinations thereof, Z═As, S, Se, Sb, or combinations thereof, x=0-0.1, and y=0-0.1, or
wherein the semiconductor material has the general formula (In₁₋ₓTlₓ)(Te_{1-y}Se_{y}), wherein x=0-1 and y=0-1.

14. The semiconductor body according to claim 13, wherein the semiconductor layer is a stoichiometric InTe layer.

15. The semiconductor body according to claim 13, wherein a surface of the semiconductor layer comprises micron- and/or nano-sized structures.

16. The semiconductor body according to claim 13, further comprising a further semiconductor layer of a further semiconductor material arranged on the semiconductor layer.

17. An optoelectronic device comprising:
the semiconductor body according to claim 13,
wherein the optoelectronic device forms at least one of the following elements: a detector, a sensor, an emitter, a switching device, or a photo responsive device.

18. The optoelectronic device according to claim 17, wherein the semiconductor body comprises a semiconductor layer and a further semiconductor layer, and wherein the semiconductor layer and the further semiconductor layer are doped differently.

19. The optoelectronic device according to claim 17, further comprising an infrared light or a visible light emitting material, wherein the emitting material is arranged on the semiconductor body or on a surface of a substrate facing away from the semiconductor body.

20. The optoelectronic device according to claim 17, further comprising an infrared light or a visible light detecting material, wherein the detecting material is arranged on the semiconductor body or on a surface of a substrate facing away from the semiconductor body.
